(19) United States
(12) Patent Application Publication
(10) Pub. No.: US 2010/0264881 A1
(43) Pub. Date: Oct. 21, 2010

(54) Battery Protection Circuit

(75) Inventors: Hang Yin, Beijing (CN); Zhao Wang, Beijing (CN); Wenbo Tian, Beijing (CN)

Correspondence Address: SILICON VALLEY PATENT AGENCY, 7394 WILDFLOWER WAY, CUPERTINO, CA, 95014, US

(73) Assignee: Vimicro Corporation

(21) Appl. No.: 12/507,537

(22) Filed: Jul. 22, 2009

(30) Foreign Application Priority Data
Apr. 21, 2009 (CN) 200910082238.2

(51) Int. Cl. H02J 7/00; H02H 3/20; H03K 17/687

(52) U.S. Cl. 320/134; 361/90; 327/434

(57) ABSTRACT

A battery protection circuit with quickly testable design is disclosed. According to one embodiment, the battery protection circuit includes a battery voltage detection circuit configured to detect a battery voltage, output an effective trigger signal if the battery voltage reaches a voltage protection threshold, and output an ineffective trigger signal otherwise; a delay circuit configured to receive the trigger signal, output an effective status signal if the trigger signal is maintained effective continuously over a period of time, and outputs an ineffective status signal otherwise; a protection driver configured to receive the trigger signal and the status signal, enter a driving state when both the trigger signal and the status signal are effective, enter a non-driving state when both the trigger signal and the status signal are ineffective, and enter a ready driving state when the trigger signal is effective and the status signal is ineffective.

### BACKGROUND OF THE INVENTION

1. Field of the Invention

The present invention relates to a field of circuit design, more particularly to a battery protection circuit with quickly testable design.

2. Description of Related Art

It is well known that a battery, such as a Lithium ion battery, has been widely used in all kinds of mobile electronic devices (e.g., cell phone, PDA, MP3 or notebook computer etc.). However, the battery may have serious safety problems when it is overcharged or overdischarged. Hence, a battery protection circuit is configured to detect charging/discharging status of the battery, and switch off the charging/discharging loop to protect the battery when the battery is being overcharged or overdischarged.

FIG. 1 is a circuit diagram 100 showing a battery protection circuit in a prior art system. The battery protection circuit 100 comprises a pair of MOS transistors QD and QC, a control integrated circuit VA7070, resistors R1 and R2, and a capacitor C1. B+ indicates an inner anode of the battery, B− indicates an cathode of the battery, P+ indicates an outer anode of the battery, and P+ indicates an outer cathode of the battery. The control IC is configured to detect a battery voltage via power terminals VDD and VSS thereof, drive the MOS transistor QD to switch on/off a discharging loop of the battery via a discharging protection terminal DOUT thereof, and drive the MOS transistor QC to switch on/off a charging loop of the battery via a charging protection terminal COUT thereof. In normal status, the charging protection terminal COUT and the discharging protection terminal DOUT are at a high level, the MOS transistors QC and QD are turned on, so the battery can be charged or discharged freely.

During charging the battery, P+ is coupled to a positive terminal of a battery charger, and P− is coupled to a negative terminal of the battery charger. The battery voltage increases gradually over the time. Once the battery voltage exceeds an overcharged voltage protection threshold which is, for example, 4.25-4.3V, the charging protection terminal COUT turns from high level to low level to drive the MOS transistor QC to switch off the charging loop of the battery, thus the battery is protected from being overcharged. In practice, there is a period of delay time which generally is about 1 second from the battery voltage exceeding the overcharged voltage protection threshold to the MOS transistor QC being switched off, thereby avoiding misjudgement brought by interference.

During discharging the battery, the control IC is configured to detect whether the battery voltage is less than an overdischarged voltage protection threshold which for example is 2.3-2.4V. If yes, the discharging protection terminal DOUT turns from a high level to a low level to drive the MOS transistor QD to switch off the discharging loop of the battery, thus the battery is protected from being overdischarged. In practice, there also is a period of delay time which generally is about 100 ms from the battery voltage being less than the overdischarged voltage protection threshold to the MOS transistor QD being switched off, thereby avoiding misjudgement brought by interference.

The battery protection circuit should be strictly tested before being put into use. For better testing result, it needs to simulate actual working condition of the battery protection circuit as much as possible. When the overdischarged voltage protection threshold or the overcharged voltage protection threshold is tested every time, it needs to actually simulate the delay operation mentioned above. In practice, the delay operation during the overdischarged protection is second magnitude, and the delay operation during the overcharged protection is hundred millisecond magnitude, thereby not only increasing difficulty of testing but also prolonging testing time.

Thus, improved techniques for a battery protection circuit with quickly testable design are desired to overcome the above disadvantages.

### SUMMARY OF THE INVENTION

This section is for the purpose of summarizing some aspects of the present invention and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present invention.

In general, the present invention related to a battery protection circuit with quickly testable design. According to one embodiment, the battery protection circuit includes a battery voltage detection circuit configured to detect a battery voltage, output an effective trigger signal if the battery voltage reaches a voltage protection threshold, and output an ineffective trigger signal otherwise; a delay circuit configured to receive the trigger signal, output an effective status signal if the trigger signal is maintained effective continuously over a period of time, and outputs an ineffective status signal otherwise; a protection driver configured to receive the trigger signal and the status signal, enter a driving state when both the trigger signal and the status signal are effective, enter a non-driving state when both the trigger signal and the status signal are ineffective, and enter a ready driving state when the trigger signal is effective and the status signal is ineffective.

One of the features, benefits and advantages in the present invention is a battery protection circuit with a greatly reduced testing time as a waiting time is neglected.

Other objects, features, and advantages of the present invention will become apparent upon examining the following detailed description of an embodiment thereof, taken in conjunction with the attached drawings.

### BRIEF DESCRIPTION OF THE DRAWINGS

These and other features, aspects, and advantages of the present invention will become better understood with regard to the following description, appended claims, and accompanying drawings where:

FIG.1 is a circuit diagram showing a battery protection circuit in the prior art;

FIG. 2 is a circuit diagram showing a protection driver in the prior art;

FIG. 3 is a block diagram showing a battery protection circuit with quickly testable design according to one embodiment of the present invention;

FIG. 4 is a block diagram showing a testing device for the battery protection circuit shown in FIG. 3;

FIG. 5 is a circuit diagram showing an exemplary configuration of a COUT protection driver of the battery protection circuit shown in FIG. 3; and

FIG. 6 is a circuit diagram showing an exemplary configuration of a DOUT protection driver of the battery protection circuit shown in FIG. 3.

### DETAILED DESCRIPTION OF THE INVENTION

The detailed description of the present invention is presented largely in terms of procedures, steps, logic blocks, processing, or other symbolic representations that directly or indirectly resemble the operations of devices or systems contemplated in the present invention. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the invention do not inherently indicate any particular order nor imply any limitations in the invention.

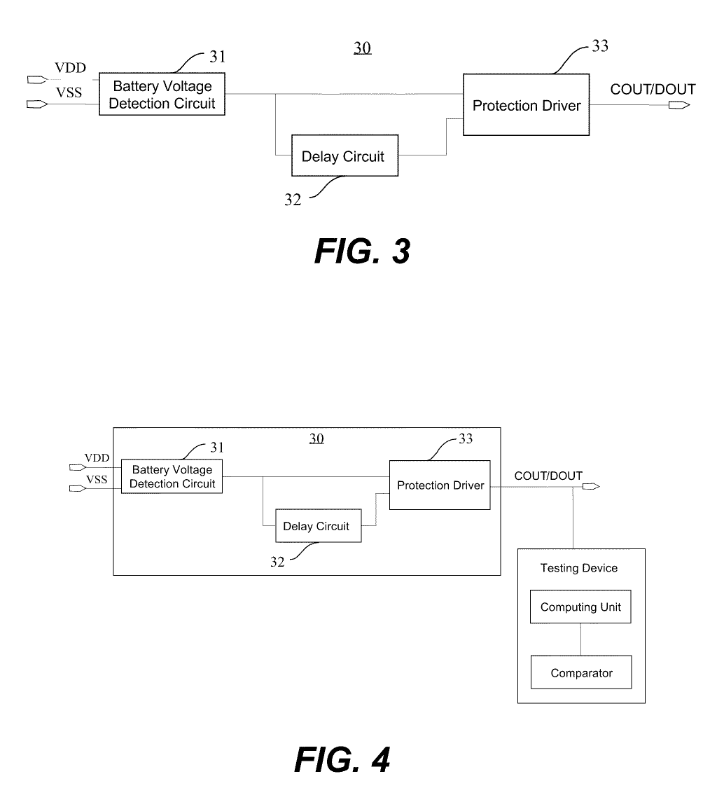

Embodiments of the present invention are discussed herein with reference to FIGS. 3-6. However, those skilled in the art will readily appreciate that the detailed description given herein with respect to these figures is for explanatory purposes only as the invention extends beyond these limited embodiments.

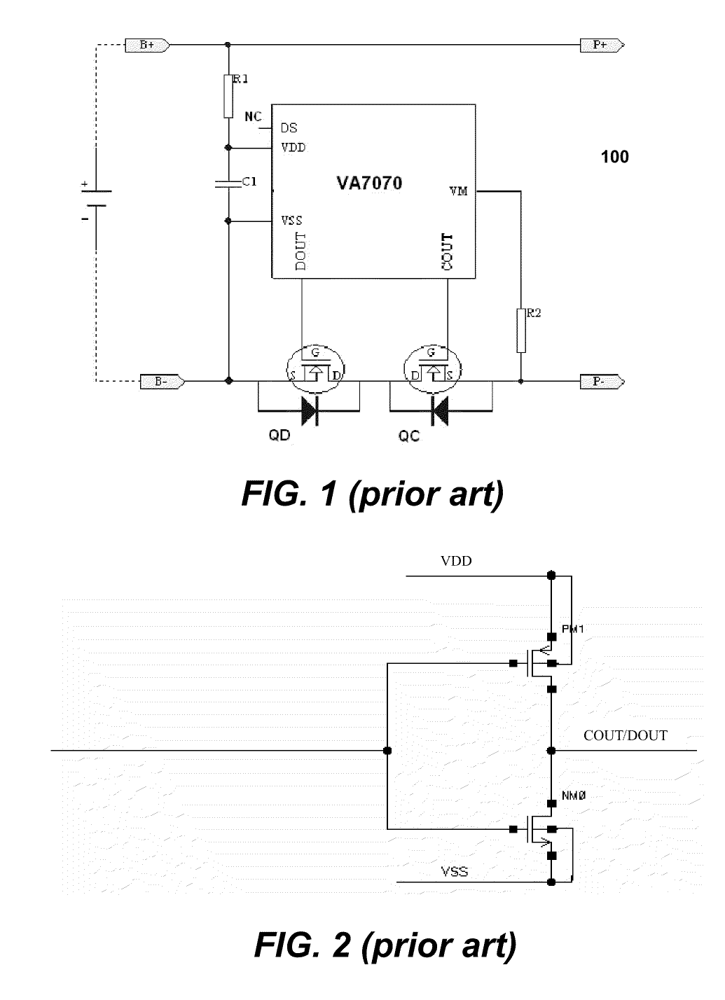

FIG. 3 is a block diagram showing a battery protection circuit with quickly testable design according to one embodiment of the present invention. The battery protection circuit 30 is coupled to a battery in practice application with reference to FIG. 1. The battery protection circuit 30 comprises a battery voltage detection circuit 31, a delay circuit 32 and a protection driver 33.

The battery voltage detection circuit 31 is configured to detect a battery voltage via power terminals VDD and VSS thereof, and determine whether the battery voltage reaches a voltage protection threshold. If yes, the batter voltage detection circuit 31 outputs an effective trigger signal, otherwise outputs an ineffective trigger signal. The delay circuit 32 is configured to receive the trigger signal from the battery voltage detection circuit 31. If the trigger signal is maintained effective continuously over a period of time also referred as a delay time, the delay circuit 32 outputs an effective status signal as a response, otherwise, outputs an ineffective status signal. In general, the power terminal VSS is grounded, and the power terminal VDD is coupled to the battery voltage.

The protection driver 33 is configured to receive the trigger signal from the battery voltage detection circuit 31 and the status signal from the delay circuit 32. When both the trigger signal and the status signal are effective, the protection driver 33 enters a driving state. At this state, the protection driver 33 outputs an effective drive signal via a protection terminal DOUT or COUT thereof to drive a MOS transistor QD or QC to switch off a discharging or charging loop of the battery. When both the trigger signal and the status signal are ineffective, the protection driver 33 enters a non-driving state. At this state, the protection driver 33 outputs an ineffective drive signal via the protection terminal DOUT or COUT thereof to drive the MOS transistor QD or QC to switch on the discharging or charging loop of the battery.

When the trigger signal is effective and the status signal is ineffective, the protection driver 33 enters a testing state, also referred as a ready driving state. It is noted that the condition of the trigger signal being ineffective and the status signal being effective is impossible because the status signal must be ineffective as long as the trigger signal is ineffective. Even if the condition of the trigger signal being ineffective and the status signal being effective appears, the protection driver 33 still enters the testing state. The ready driving state is substantially identical with the non-driving state for the protection driver 33 in practice applications. The protection driver 33 still outputs the ineffective drive signal to turn on the MOS transistor QD or QC in the ready driving state. Hence, the battery protection circuit 30 with the ready driving state according to one embodiment of the present invention can work normally in practice applications.

However, the ready driving state is different from the non-driving state for the protection driver 33 when the battery protection circuit 30 is tested. The difference between the ready driving state and the non-driving state can be determined by detecting the protection terminal DOUT or COUT. In other words, the state the protection driver 33 enters is the ready driving state or the non-driving state can be distinguished by detecting the protection terminal DOUT or COUT. It can be observed that the protection driver 33 enters the ready driving state immediately in response to the effective trigger signal. The voltage applied between the power terminal VDD and VSS of the battery voltage detection circuit can be adjusted quickly during testing the battery protection circuit 30 until the protection driver 33 enters into the ready driving state because a delay time between the effective trigger signal and the effective status signal introduced by the delay circuit 32 is neglected. As a result, the battery protection circuit 30 with the ready driving state according to one embodiment of the present invention can be tested quickly before being put into use.

FIG. 4 is a block diagram showing a testing device 40 for the battery protection circuit 30 shown in FIG. 3. The testing device 40 comprises a computing unit 41 and a comparator 42. When the battery protection circuit 30 is tested, the power terminal VSS is grounded, and the power terminal VDD is coupled to a voltage simulating the battery voltage. Additionally, a resistor (not shown) is coupled between the protection terminal DOUT or COUT and the ground. For simulating the battery voltage, the voltage of the power terminal VDD is adjusted with a predetermined voltage interval (e.g. 10 mV) successively. The computing unit 41 is configured to compute a difference between the voltage of the power terminal VDD and the voltage of the protection terminal DOUT or COUT. The comparator 42 is configured to compare a current difference after the voltage of the power terminal VDD is adjusted this time with a previous difference before the voltage of the power terminal VDD is adjusted this time, determine whether a difference between the current difference and the previous difference is larger than a voltage threshold. If yes, which means that the protection driver 33 enters into the ready driving state, a testing result is fed back to stop the testing process, otherwise, which means that the protection driver 33 still is in the non-driving state, the voltage of the power terminal VDD is adjusted to continue the testing process.

In the prior art, it requires to wait a period of time being equal to the delay time for the comparing result after the voltage of the power terminal VDD is adjusted, so the testing time is very long. However, the testing time in the current embodiment of the present invention is greatly reduced because the waiting time is neglected.

In one embodiment, the battery protection circuit 30 is implemented as a battery overcharging protection circuit. So, the batter voltage detection circuit 31 outputs the effective trigger signal if the battery voltage exceeds an overcharging voltage protection threshold THR1, otherwise the batter voltage detection circuit 31 outputs the ineffective trigger signal. When both the trigger signal and the status signal are effective, the protection driver 33 outputs the effective drive signal via the protection terminal COUT thereof to drive the MOS transistor QC to switch off the charging loop of the battery. When both the trigger signal and the status signal are ineffective, the protection driver 33 outputs the ineffective drive signal via the protection terminal COUT thereof to drive the MOS transistor QC to switch on the charging loop of the battery. For actually simulating the battery voltage during the charging process, the voltage of the power terminal VDD is increased with the predetermined voltage interval successively.

In anther embodiment, the battery protection circuit 30 is implemented as a battery overdischarging protection circuit. So, the batter voltage detection circuit 31 outputs the effective trigger signal if the battery voltage is less than an overdischarging voltage protection threshold THR2, otherwise the batter voltage detection circuit 31 outputs the ineffective trigger signal. When both the trigger signal and the status signal are effective, the protection driver 33 outputs the effective drive signal via the protection terminal DOUT thereof to drive the MOS transistor QD to switch off the discharging loop of the battery. When both the trigger signal and the status signal are ineffective, the protection driver 33 outputs the ineffective drive signal via the protection terminal DOUT thereof to c to switch on the discharging loop of the battery. For actually simulating the battery voltage during the discharging process, the voltage of the power terminal VDD is increased with the predetermined voltage interval successively.

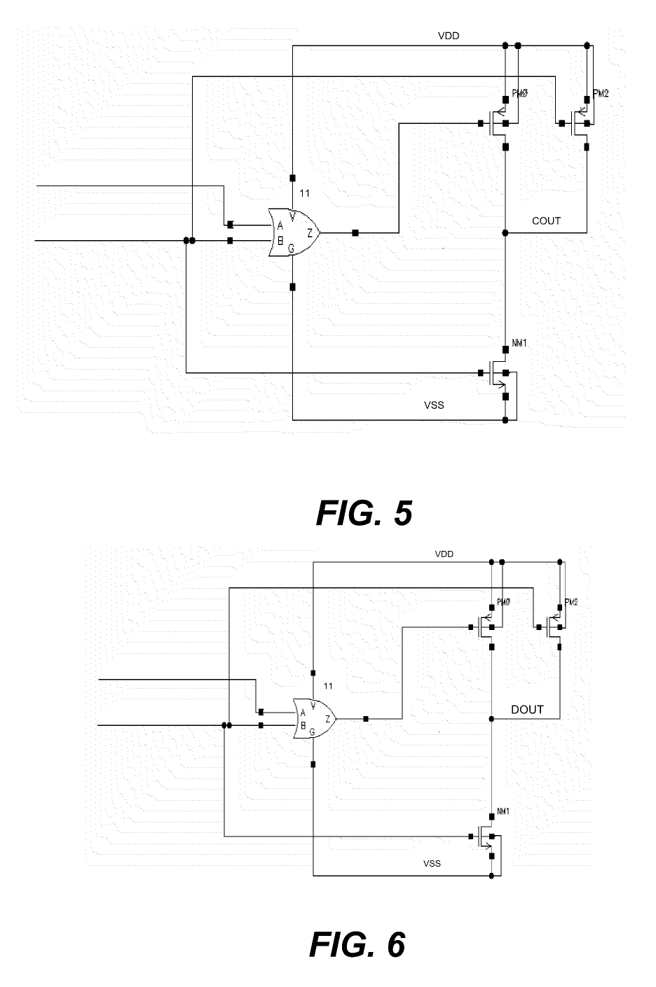

FIG. 5 is a circuit diagram showing an exemplary configuration of a COUT protection driver of the battery protection circuit 30 shown in FIG. 3, wherein the battery protection circuit 30 is the overcharging battery protection circuit at this time. Referring to FIG.5, the protection driver comprises an OR gate 11 and a pair of PMOS transistors PM0 and PM2, and a NMOS transistor NM1. One input A of the OR gate 11 is configured to receive the trigger signal, the other input B of the OR gate 11 is configured to receive the status signal, and an output Z of the OR gate 11 is coupled to a gate of the PMOS transistor PM0. A source of the PMOS transistors PM0 is coupled to the power terminal VDD, and a drain of the PMOS transistor PM0 is coupled to the protection terminal COUT A gate of the PMOS transistor PM2 is configured to receive the status signal, a source of the PMOS transistor PM2 is coupled to the power terminal VDD, and a drain of the PMOS transistor PM0 is coupled to the protection terminal COUT Agate of the NMOS transistor NM1 is configured to receive the status signal, a source of the NMOS transistor NM1 is coupled to the power terminal VSS, and a drain of the NMOS transistor NM1 is coupled to the protection terminal COUT

In this embodiment, the high level is effective for the trigger signal and the status signal, and the low level is effective for the drive signal.

In operation, when both the trigger signal and the status signal are effective (high level), the PMOS transistors PM2 and PM0 both switch off, and the NMOS transistors NM1 switch on, so the protection terminal is pulled down to the low level (effective) to drive the MOS transistor QC to switch off the charging loop. At this time, the protection driver enters the driving state. When both the trigger signal and the status signal are ineffective (low level), the PMOS transistors PM2 and PM0 both switch on, and the NMOS transistors NM1 switch off, so the protection terminal COUT is pulled up to the high level (ineffective) to drive the MOS transistor QC to switch on the charging loop. At this time, the protection driver enters the non-driving state.

When the trigger signal is effective (high level) and the status signal is ineffective (low), the PMOS transistors PM2 switches on, the PMOS transistors PM0 switches off, and the NMOS transistors NM1 switch off, so the protection terminal is still pulled up to the high level (ineffective). At this time, the protection driver enters the ready driving state. Hence, the ready driving state is substantially identical with the non-driving state for the protection driver in practice applications.

When the battery protection circuit is tested, the power terminal VSS is grounded, the power terminal VDD is coupled to the voltage simulating the battery voltage, and a pull-down resistor (not shown) is coupled between the protection terminal COUT and the ground. It can be seen that the resistance between the power terminal VDD and the protection terminal COUT in the ready driving state is larger than that between the power terminal VDD and the protection terminal COUT in the non-driving state because only one of PM2 and PM0 switches on in the ready driving state and both PM2 and PM0 switches on in the non-driving state. Hence, the ready driving state and the non-driving state can be distinguished by detecting the voltage drop between the power terminal VDD and the protection terminal COUT.

A method for testing the overcharging battery protection circuit comprises: initializing or increasing the voltage of the power terminal VDD with the predetermined voltage interval (e.g. 10 mV); obtaining the voltage of the protection terminal COUT; computing the difference between the voltage of the power terminal VDD and the voltage of the protection terminal COUT, comparing a current difference after increasing the voltage of the power terminal VDD this time with a previous difference before increasing the voltage of the power terminal VDD; determining whether a difference between the current difference and the previous difference is larger than the voltage threshold; If yes, which means that the protection driver enters into the ready driving state, feeding back a testing result to stop the testing process, otherwise, which means that the protection driver still is in the non-driving state, returning to the process of increasing the power terminal VDD.

Next, an example of the testing method is illustrated hereafter:

S1: initializing VDD=4V;

S2: obtaining V_{COUT}=3.8V;

S3: computing V_{drop1}=0.2V;

S4: increasing VDD by 0.2V, VDD=4.2V;

S5: obtaining V_{COUT}=4V;

S6: computing V_{drop2}=0.2V;

S7: comparing V_{drop1} with V_{drop2}, concluding that the difference is 0 and less than the voltage threshold 0.2V, continuing the testing process;

S8: increasing VDD by 0.1V, VDD=4.3V;

S9: obtaining V_{COUT}=3.8V;

S10: computing V_{drop3}=0.5V;

S11: comparing V_{drop2} with V_{drop3}, concluding that the difference is 0.3V and larger than the voltage threshold 0.2V, outputting a testing result and determining the current voltage of VDD 4.3V is the overcharging voltage protection threshold THR1 of the battery protection circuit.

The protection driver shown in FIG. 5 is able to directly response to the trigger signal in testing. So, the testing time of the battery protection circuit is greatly reduced.

FIG. 6 is a circuit diagram showing an exemplary configuration of a DOUT protection driver of the battery protection circuit 30 shown in FIG. 3, wherein the battery protection circuit 30 is the overdischarging battery protection circuit at this time. The DOUT protection driver shown in FIG. 6 is identical with the COUT protection driver shown in FIG. 5 except that the protection terminal DOUT of the DOUT protection driver is provided for driving the MOS transistor QD. A method for testing the overdischarging battery protection circuit with the protection driver shown in FIG. 6 also refers to that for testing the overcharging battery protection circuit with the protection driver shown in FIG. 5.

In FIG. 5 and FIG. 6, the high level is effective for the trigger signal and the status signal, and the low level is effective for the drive signal. If the high level is effective for the drive signal, the configuration of the protection driver shown in FIG. 5 and FIG. 6 should be modified correspondingly. The protection driver comprises a pair of NMOS transistors connected in parallel, a PMOS transistor connected to the NMOS transistors in series, and an AND gate. A gate of one NMOS transistor is coupled to an output of the AND gate, a gate of the other NMOS transistor receives the status signal, and a gate of the PMOS transistor receives the status signal too. At this time, the low level is effective for the trigger signal and the status signal.

FIG. 2 is a circuit diagram showing a protection driver in the prior art. The protection driver comprises a PMOS transistor PM1 and a NMOS transistor NM0 connected with the PMOS transistor PM1 in series. Agate of the PMOS transistor PM1 receives the status signal, and a gate of the NMOS transistor NM0 receives the status signal too. The protection driver shown in FIG. 2 has two working states, one is a driving state, and the other is a non-driving state.

The present invention has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the invention as claimed. Accordingly, the scope of the present invention is defined by the appended claims rather than the foregoing description of embodiments.

What is claimed is:

1. A battery protection circuit comprising:
a battery voltage detection circuit configured to detect a battery voltage, output an effective trigger signal if the battery voltage reaches a voltage protection threshold, and output an ineffective trigger signal otherwise;
a delay circuit configured to receive the trigger signal, output an effective status signal if the trigger signal is maintained effective continuously over a period of time, and outputs an ineffective status signal otherwise;
a protection driver configured to receive the trigger signal and the status signal, enter a driving state when both the trigger signal and the status signal are effective, enter a non-driving state when both the trigger signal and the status signal are ineffective, and enter a ready driving state when the trigger signal is effective and the status signal is ineffective.

2. The battery protection circuit according to claim 1, wherein
the protection driver outputs an effective drive signal via a protection terminal thereof to drive a MOS transistor to switch off a discharging or charging loop of a battery in the driving state;
the protection driver outputs an ineffective drive signal via the protection terminal thereof to drive the MOS transistor to switch on the discharging or charging loop of the battery in the non-driving state;
the protection driver still outputs the ineffective drive signal via the protection terminal thereof to drive the MOS transistor to switch on the discharging or charging loop of the battery in the ready driving state; and wherein
the ready driving state and the non-driving state are able to be distinguished by detecting the protection terminal.

3. The battery protection circuit according to claim 1, wherein the protection driver comprises a first switch circuit, a second switch circuit connected with the first switch circuit in parallel, a third switch circuit connected with the first switch circuit and the second switch circuit in series, and a logic circuit, and a node between the first switch circuit and the third switch circuit serves as the protection terminal, and wherein
one input of the logic circuit is coupled to receive the status signal, the other input of the logic circuit is coupled to receive the trigger signal, and an output of the logic circuit is coupled to a control terminal of the first switch circuit;
a control terminal of the third switch circuit is coupled to receive the status signal, a control terminal of the second switch circuit is coupled to receive the status signal.

4. The battery protection circuit according to claim 3, wherein
the first switch circuit and the second switch circuit switch on, the third switch circuit switches off in the non-driving state;
the first switch circuit and the second switch circuit switch off, the third switch circuit switches on in the driving state; and
the first switch circuit and the third switch circuit switch off, the second switch circuit switches on in the ready driving state.

5. The battery protection circuit according to claim 3, wherein
the first switch circuit is a PMOS transistor, the second switch circuit is a PMOS transistor, the third switch circuit is a NMOS transistor, and the logic circuit is a OR gate.

6. The battery protection circuit according to claim 3, wherein
the first switch circuit is a NMOS transistor, the second switch circuit is a NMOS transistor, the third switch circuit is a PMOS transistor, and the logic circuit is an AND gate.

7. The battery protection circuit according to claim 3, wherein the battery voltage detection circuit outputs the effective trigger signal if the battery voltage exceeds an overcharging voltage protection threshold, and outputs the ineffective trigger signal otherwise.

8. The battery protection circuit according to claim 3, wherein the battery voltage detection circuit outputs the effective trigger signal if the battery voltage is less than an overdischarging voltage protection threshold, and outputs the ineffective trigger signal otherwise.

9. A protection driver, comprises:
a first switch circuit;
a second switch circuit connected with the first switch circuit in parallel;
a third switch circuit connected with the first switch circuit and the second switch circuit in series;
a logic circuit having a pair of inputs and an output, one input of the logic circuit being coupled to a control terminal of the second switch circuit and a control terminal of the third switch circuit, the output of the logic circuit being coupled to a control terminal of the third switch; and wherein
one of the third switch circuit and the second switch circuit switches on, and the other of the third switch circuit and the second switch circuit switches off at the same time.

10. The protection driver according to claim 10, wherein
the first switch circuit is a PMOS transistor, the second switch circuit is a PMOS transistor, the third switch circuit is a NMOS transistor, and the logic circuit is a OR gate.

11. The protection driver according to claim 10, wherein
the first switch circuit is a NMOS transistor, the second switch circuit is a NMOS transistor, the third switch circuit is a PMOS transistor, and the logic circuit is an AND gate.
